(19) United States
(12) Patent Application Publication
(10) Pub. No.: US 2010/0080672 A1
(43) Pub. Date: Apr. 1, 2010

(54) Direct loading to and from a conveyor system

(75) Inventors: Anthony C. Bonora, (US); Joseph Fatula, (US); Roumen Iliev Deyanov, (US); Hiroshi Ito, (US); Roger G. Hine, (US)

Correspondence Address: FISH & RICHARDSON PC, P.O. BOX 1022, MINNEAPOLIS, MN, 55440-1022, US

(73) Assignee: Asyst Technologies, Inc.

(21) Appl. No.: 12/456,645

(22) Filed: Jun. 19, 2009

Related U.S. Application Data
(60) Provisional application No. 61/074,594, filed on Jun. 20, 2008.

(51) Int. Cl. H01L 21/677; B65G 15/20; B65G 15/22

(52) U.S. Cl. 414/222.01; 198/817; 198/602

(57) ABSTRACT

A direct load system and conveyor is disclosed. The direct load system includes a load port for moving containers in a vertical orientation between a lower position near the conveyor and up to an upper position proximate to a load port door. The load port includes a single arm that moves a support in a vertical configuration, such that moving the single arm allows for the support to be lowered to the conveyor in a nested location between beams of the conveyor. The conveyor includes a single slot in a beam that allows the single arm to pass, and allows the support to be placed in the nested location, which is below a conveyor path defined by the belts of the conveyor. If a container is to be lifted off of the belts, the single arm raises up from the nested location, to then raise the container up and off of the conveyor and to the load port door. The single arm and interface with the conveyor slot can be used by other tools, such as stockers or tools that need to directly access a conveyor used to transport containers (e.g., wafers, etc.) to locations/tools of a fabrication facility. In alternate embodiments, it is possible to replace the belt with conveying wheels.

### CLAIM OF PRIORITY

This application claims the priority of U.S. Provisional Application No. 61/074,594, filed on Jun. 20, 2008, and titled “Direct Loading To and From a Conveyor System”. This application is incorporated herein by reference in their entireties for all purposes.

### CROSS-REFERENCE TO RELATED APPLICATIONS

This application is related to (1) U.S. application Ser. No. 11/484,218 (ASTGP135), filed on Jul. 10, 2006, entitled “Belt Conveyor for Use with Semiconductor Containers”, and (2) U.S. application Ser. No. 11/064,880 (ASTGP125), filed on Feb. 24, 2005, entitled “Direct Tool Loading”. Both Applications are herein incorporated by reference.

### BACKGROUND

There are several ways that semiconductor wafer containers are transported in a semiconductor fabrication facility (“fab”). A system for transporting a container is often referred to as an Automated Material Transport System (“AMHS”) or simply as a material transport system. A material transport system may refer to a part or all of the overall system. A fab may use only one type of AMHS throughout the fab, or there may be different types of AMHS in certain areas, or different types of AMHS for different transportation functions. Some of these AMHS types use vehicles to hold the container as it is being transported, such as a rail guided vehicle (RGV) or an automated guided vehicle (AGV). Material transport systems utilizing RGVs or AGVs require managing empty vehicles to arrange their arrival at sites where containers are to be picked up. Waiting for the arrival of such vehicles causes AMHS delays and the management of the vehicle movement increases the complexity of the AMHS. The same issues exist when moving containers with an Overhead Hoist Transport (OHT) system.

Conveyor systems are more efficient at moving containers within a fab without any, or a minimum number of, vehicle delays, and do not have to manage empty vehicles. Conveyors directly move the containers without any material or mechanical interface that comes between the conveyor surfaces and the container surfaces. Unless the conveyor is full, it is capable of immediately receiving a container for transport. For these, and other, reasons, conveyors may provide a very high throughput AMHS.

One example of a conveyor system is disclosed in U.S. Pat. No. 6,223,886, entitled “Integrated Roller Transport Pod and Asynchronous Conveyor,” which is owned by Asyst Technologies, Inc., and is incorporated in its entirety herein. The drive rail 12 includes a drive system, generally designated at 38 in FIG. 1A, for propelling a container 2 along the rails 12. The drive system 38 includes a plurality of separate drive assemblies 40. Each drive assembly 40 includes a plurality of drive wheels 42 which frictionally engage the underside of the container 2 to propel the container 2 along the drive rail 12 for a specific zone Z. As shown in FIG. 1A, the drive assemblies 40 are located along the rail such that the separation between the outermost drive wheels 42 of adjacent drive assemblies 40 is substantially equal to the spacing between the drive wheels 42 of the individual drive assembly 40. The drive wheels 42 project upwardly from the drive rail housing such that it is the drive wheels 42 of the rail 12 which directly support the transport container 2. The wheels 42 are preferably mounted at approximately the same height to minimize tipping or rocking of the container 2 as it is moved along the rails 12. It is also known within the art to individually mount a passive wheel 43 between each drive wheel 42 (as shown in FIG. 1A).

Although conveyor systems of various types have provided movement of objects, the interface between conveyor systems and other equipment still need improvements in efficiencies. Examples of conveyor interfacing are shown in U.S. Pat. No. 6,481,558, but although such interface works well, it may cause FOUPs to wait during interfaces with the conveyor. This patent is herein incorporated by reference.

It is in this context that embodiments in accordance with the invention arise.

### SUMMARY

Inventions for a direct loading system and conveyor are provided. As used herein, direct loading refers to loading material from a conveyor system directly to a tool that is located substantially adjacent to the conveyor. The loading, in one embodiment, is done by a load port module. The load port module can be a single load port module or part of a multi-load port system. In either configuration, the load port module is configured with an arm that holds a support. In still a further embodiment, the arm is a single arm. A track is provided along a vertical orientation of the load port that allows the single arm to move vertically up and down. When the arm moves down, the arm moves in the direction of a conveyor system. The conveyor system may be installed on a floor of a fabrication facility, on a platform over the floor, or in a section built into the floor.

The arm is configured to move the support, held by the arm, down and into a space of the conveyor system. The space is defined between two beams of a conveyor segment. In one embodiment, two or more conveyor segments define a conveyor. The load port, using the single arm, can therefore lower the support down into the conveyor, at a location below the conveying path (defined by belts of the conveyor), and when material traveling on the conveyor reaches the location of the load port (if that material is destined for that particular load port), the conveyor can lift up and raise the material to an upper position of the load port. In the upper position, the load port provides the material to a location that will allow interfacing with tools that the load port services (e.g., provides material). In one specific embodiment, the load port is configured to lower into the conveyor that is arranged beside the load port (e.g., near a lower region of the load port), and the conveyor moves a container (e.g., FOUP) to the load port location. The single arm can then raise the support and lift the container off of the conveyor to an upper position. It should be understood, that if the container is not destined (i.e., assigned) to the particular load port, the conveyor will not stop the container in front of the load port, and the support of the load port (if in the down position), will not impede, obstruct, prevent or interfere with the transfer of the container along the conveyor. If the load port has raised the container off of the conveyor, the container being in the upper position will also allow other containers traveling on the conveyor (that is beside the load port) to move unobstructed. Thus, the upper position is sufficiently high enough so that containers on the conveyor can travel even when the load port has already directly loaded a container off of the conveyor and to the upper position. As used herein, discussion is provided with regard to moving containers.

In one embodiment, a direct loading tool is disclosed. The tool includes a conveyor oriented along a direction, and the conveyor is integrated proximate to first position. The conveyor includes a first beam and a second beam, and each of the first and second beams support wheels that respectively move a first belt and second belt. The first beam and the second beam are spaced apart in a parallel orientation, and the first beam including a single slot. A load port is oriented adjacent to the first beam of the conveyor. The load port includes a load port opening defined proximate to a second position, and a track defined along a vertical direction between the first position of the conveyor and the second position. A single arm is configured to move along the track between the first position and the second position, such that the single arm is configured to move through the single slot when positioned at the first position. A support is connected to the single arm, and the support is moved in the vertical direction so as to place the support between the first and second beams when the single arm is in the single slot at the first position.

In another embodiment, the conveyor is provided with a load port interface segment. The load port interface segment includes at least two beam segments. One side of the beam segment is continuous and the other beam segment is not. Generally speaking, the beam segment that is not continuous is on the side of the load port. A slot is defined in the beam segment that is not continuous. The slot is configured to allow the single arm of the load port to be lowed into the slot, and thus allows the support of the load port to be placed between the two beam segments of the load port interface segment. In sections where a load port is not located, no slot is provided, and both beams of the conveyor segment are the same. More detail with be provided below with reference to the drawings.

With reference to the conveyor, cartridge modules are used on the beams of a conveyor segment. Although the conveyor is defined by multiple segments, it is envisioned that longer beams can be used, while still using multiple conveyor cartridges along the longer beams. If a longer beam is used, a slot is defined on the beam at the locations of the load ports. The slot, as noted above, is provided to enable an arm of the load port to lower an support below a conveyor path plane. If the load port is to lift a container, the single arm moves up, lifting the container to an upper position.

In one embodiment, the cartridge includes a number of wheels, which are designed as a unit for a conveyor section and the wheels of the cartridge are designed to hold a belt. In other embodiments, the wheels are not required to be part of a cartridge, and can be individually added to provide the necessary support to a belt. A conveyor section, in one optional embodiment, includes integrated sensors for detecting the presence of a container (e.g., FOUP). Each conveyor section may implement precision sheet metal rails that facilitate high speed FOUP transport. In one embodiment, each conveyor section has two sides. Each side has a cartridge that has a belt. In particular embodiments, one side of the conveyor section includes a drive motor, that drives the conveyor. In other embodiments, both sides can have their own motor, thus eliminating the need for a drive shaft.

When the drive shaft is provided, the drive is connected to the other side of the conveyor section using a quick connect-disconnect drive shaft. The drive shaft, in one embodiment, provides for a substantially constant velocity for each of the two belts of the conveyor section. In particular embodiments, due to the flexible modularity of the conveyor sections, particular sections can be disassembled, without having to disturb adjacent sections not being removed or serviced. Removal, in some cases, will be needed for servicing, or adjustments. Conveyor systems used to handle material in semiconductor fabs require high reliability and at the same time quick access for repair in the event of a failure and/or maintenance. To address both issues, embodiments of the conveyor system provide straight sections that have been reduced to basic elements. Examples of these elements include the supporting structure, the drive system with integrated sensors, a modular cartridge for holding wheel rollers that support and drive a belt. The supporting structure could be, but not limited to, a metal frame (e.g., sheet metal channel) with a purpose to provide structural support and accurate location of a modular cartridge. In one embodiment, the cartridge system includes pod position sensors, drive system with idler wheels, interconnect boards with on-board diagnostic display and belt adjustment.

In one alternative embodiment, the belts can be eliminated, and in place, rollers can be used. Examples of the rollers are shown in FIG. 1A. Thus, although FIG. 1A shows a prior art configuration that does not allow nesting of the support by a single arm 306, the rollers of FIG. 1A can be used in place of the belt configuration. If the rollers are used, the transport level provided by the rollers should be above the level of the Kinematic plate 304. Consequently, all of the embodiments defined herein work well if the belt is replaced to define a second embodiment.

It would be advantageous to provide direct load and conveyor system that improves the performance of conventional material transport reduces the costs of AMHS, and provides for more dynamic configurations.

### BRIEF DESCRIPTION OF DRAWINGS

The present invention will be readily understood by the following detailed description in conjunction with the accompanying drawings. To facilitate this description, like reference numerals designate like structural elements.

FIG. 1A illustrates a prior art conveyor system.

FIG. 1B illustrates a conveyor section being located next to load ports and processing tools.

FIG. 2 illustrates a conveyor moving a FOUP along a direction using belts of the conveyor, in accordance with one embodiment of the present invention.

FIG. 3 illustrates a more detailed view of a cartridge module used to move a belt, in accordance with one embodiment of the present invention.

FIGS. 3A-3K illustrate various types of belt configurations, in accordance with one embodiment of the present invention.

FIG. 4 illustrates an example of a slot defined in a conveyor segment, in accordance with one embodiment of the present invention.

FIG. 5A-5D illustrate examples of a load port interfacing with a conveyor, in accordance with one embodiment of the present invention.

FIG. 6 illustrates a more detailed view of a load port arm lowered in a nested orientation within the conveyor, in accordance with one embodiment of the present invention.

FIGS. 7A-7B illustrate examples of a multi-load port system, in accordance with one embodiment of the present invention.

FIGS. 8A-8D illustrate examples of interfaces between direct loads exchanged between a conveyor and a load port, in accordance with one embodiment of the present invention.

### DETAILED DESCRIPTION

Broadly speaking, the invention defines direct load and conveyor system. The system allows for loading and unloading of containers directly to and from a conveyor. The conveyor is positioned adjacent to a loading system. In one embodiment, the loading system is a load port. The load port is configured with a single arm, and the single arm is configured to move a support up and down, in the vertical direction. The single arm is configured to move down and then nest between beams of the conveyor, still allowing containers to travel along the conveyor unobstructed. A conveyor beam is configured to include a slot adjacent to the load port, so that the single arm of the load port can fit therein, and lower the support into the nested position within the conveyor. If the container is assigned to the load port, the single arm can raise the support up and engage the container. The container can then be moved up and off of the conveyor. In the upper position, the container can be made to interface with a door of the load port. The door of the load port can then engage a container door of the container, remove the container door, and then allow a robot to move material in or out of the container.

The cartridge module described herein offers quick serviceability and off-line testing/calibration. In the event that a motor, belt or idler pulley fails, a small section can be replaced as a unit, and repaired off-line. The cartridge module can be populated with different components in order to make it a driver or a follower unit.

The scaling of these embodiments is not restricted to semiconductor wafers pods (FOUP), but it can be scaled to handle large flat panel display cassette, solar panels or PCB assembly conveyor systems. The cartridge concept described in this application can be made using a number of materials and manufacturing methods to further integrate parts and increase its modularity feature.

The direct drive modular belt conveyor cartridge with integrated systems include a direct drive system that couples a motor to a drive pulley with a plurality of idler wheels. In one embodiment, the belt tension is provided by a spring loaded shaft pushing on an idler wheel. The idler wheel in turn provides the necessary belt tension. The follower cartridge is powered via a drive shaft connecting the drive section to the driven cartridge. The drive shaft is designed such that a reduced backlash condition exist between both sections. As noted, one embodiment of the drive shaft is its designed quick disconnect scheme for fast removal and installation. Still in line with one embodiment, a hall sensor may be mounted on the opposite idler wheel on both cartridges in order to sense if a belt has failed. The sensors used to monitor the position of the pod can be mounted on the cartridge and connected to a small circuit board. The circuit board may use LED lights to provide sensor status to the operator. In one embodiment, the circuit board may be on the drive cartridge.

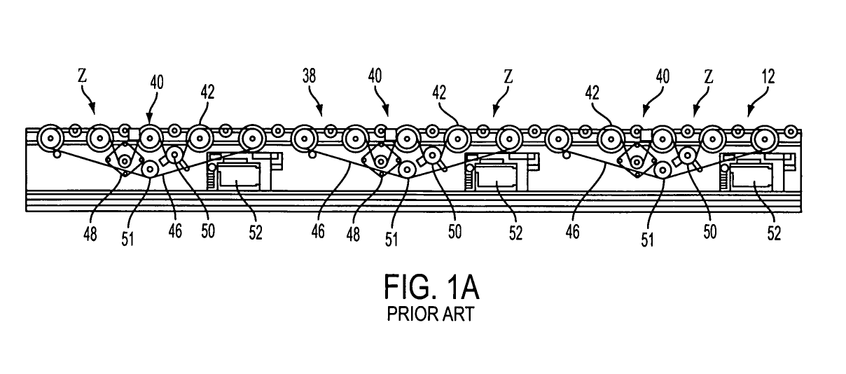

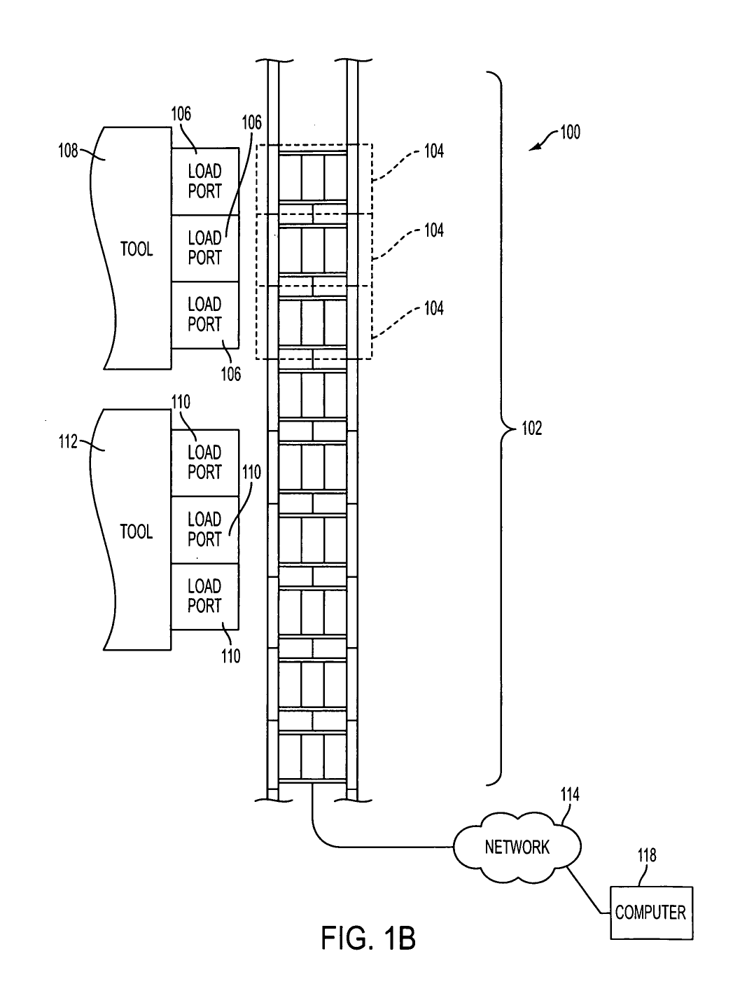

FIG. 1B shows an exemplary view of a processing area 100 in accordance with one embodiment of the present invention. The processing area 100 can, for example, be a fabrication facility, a clean room, etc. The processing area 100 can include a conveyor 102 that is made up of multiple conveyor segments 104. Conveyor 102 is designed for floor installation, although, the component parts are equally applicable to ceiling hung conveyor systems. The conveyor 102 can be configured to transport materials to and from tool 112 and tool 108. In one embodiment, semiconductor substrates are transported along the conveyor 102 in Front Opening Unified Pods (FOUPs) (not shown). A FOUP traveling along the conveyor 102 can be loaded into load port 106 or load port 110 and the semiconductor substrates can be processed within tool 108 or tool 112 respectively.

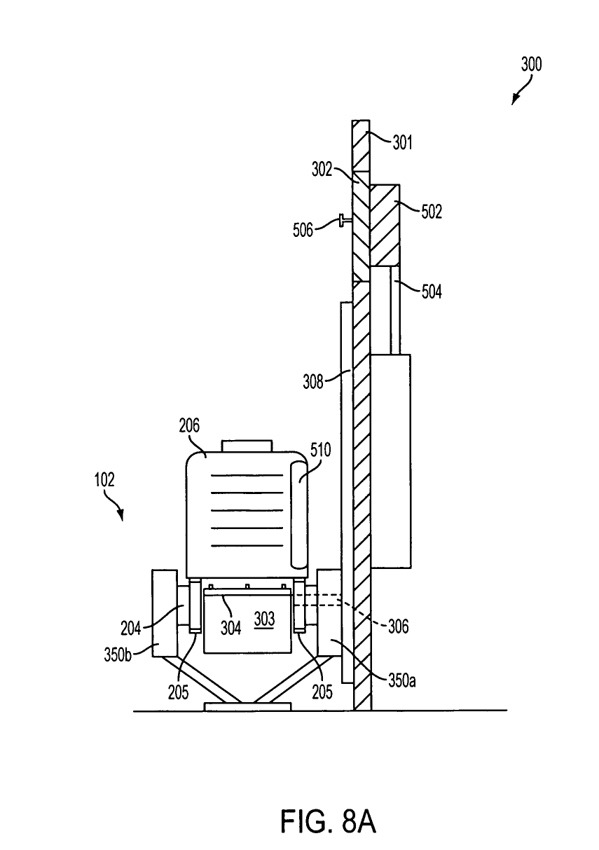

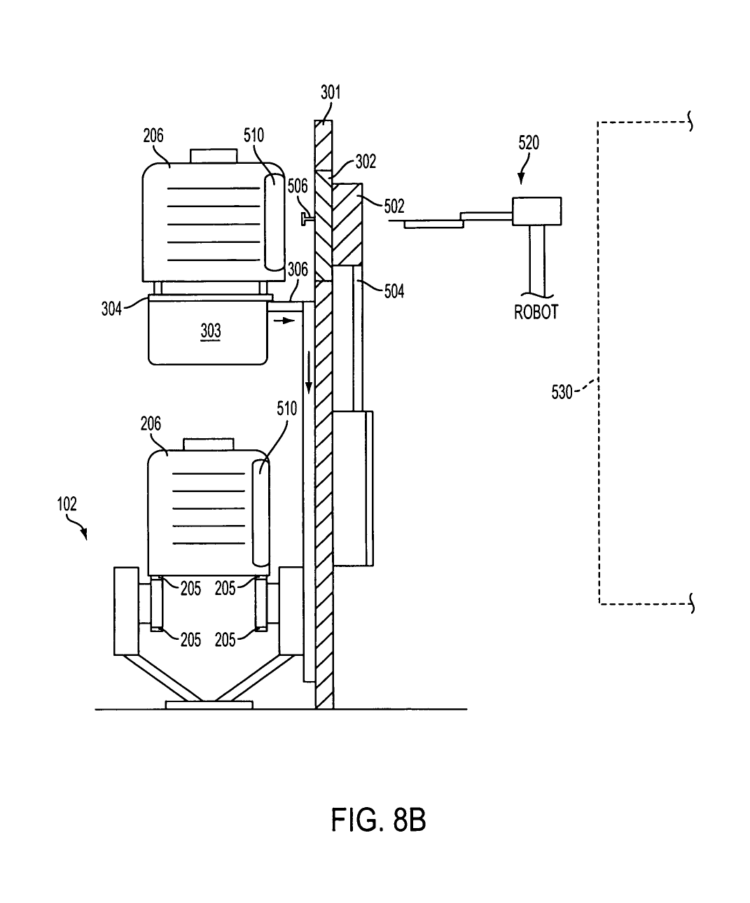

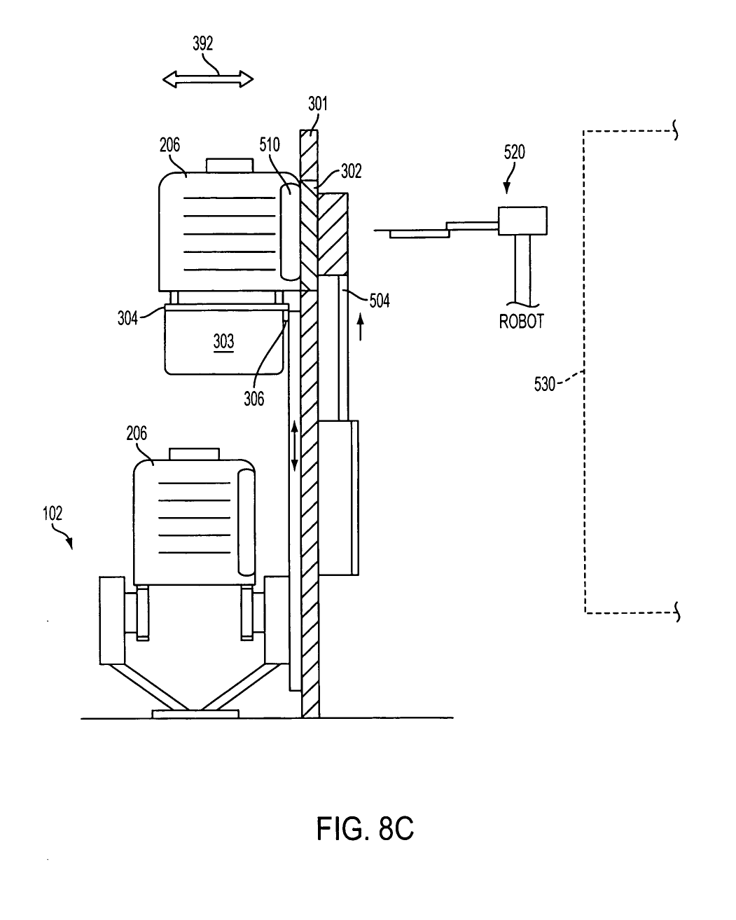

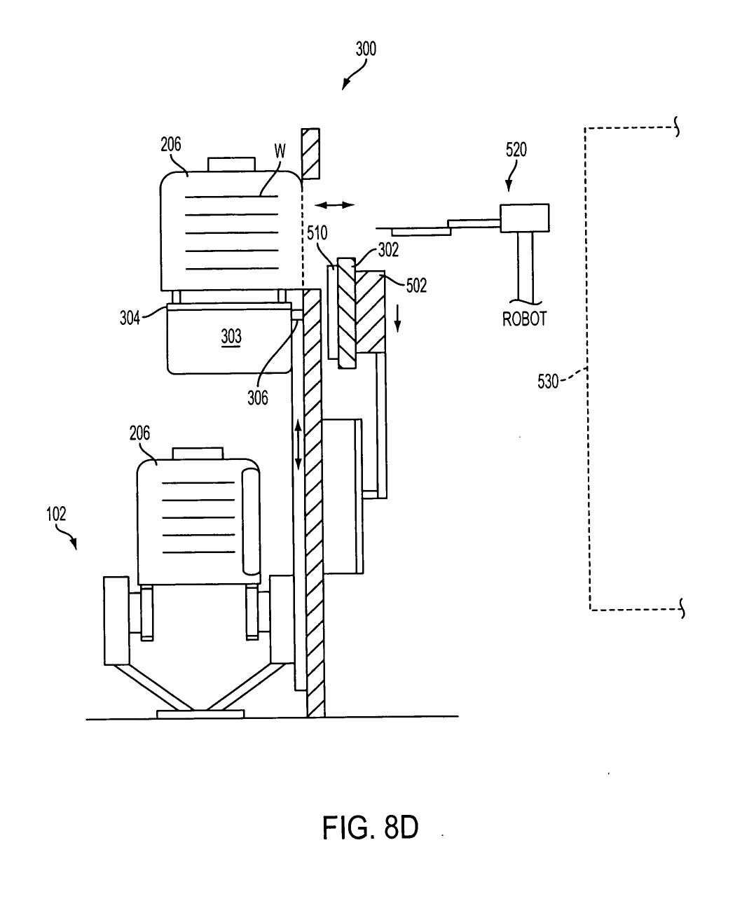

This diagram is provided for ease of illustration, but is not intended to show the relationship of the load ports to the conveyor 102. In the detailed examples provided below, it will be shown that the load ports are actually in close proximity to the conveyor 102, that lies below and beside the load ports. FIGS. 8A-8D illustrate the orientation. The close adjacent configuration will allow for the efficient direct loading of containers directly from the conveyor 102 to the load port and tools.

In more full scale implementations, conveyors can be routed throughout a floor of a fabrication facility. Fabrication facilities can integrated in single floor buildings or on multiple floors of larger buildings. In production, the conveyor systems can stretch many meters, and even miles. The number of tools in a facility can be one tool or many thousands of tools.

In one embodiment, tool 108 and tool 112 can be machines used in the processing of semiconductor substrates. Tool 108 and tool 112 may be the same tool or entirely different tools that perform similar or different functions. These fabrication functions can include, for instance, etching, deposition, photolithography, cleaning, metrology, etc. In the embodiment illustrated in FIG. 1B, each tool 108/112 has three load ports 106/110. This is merely illustrative of one embodiment and in other embodiments, more or fewer load ports could be associated with each respective tool.

In one embodiment, the conveyor segments 104 are modular assemblies that permit rapid service and maintenance of the conveyor 102. To facilitate rapid service and maintenance, each conveyor segment 104 can include belt modules, or belt cartridges that can be rapidly removed and replaced in order to minimize downtime for the conveyor 102. Each conveyor segment 104 can also include a motor to drive the belt modules along with a computer controller to activate and deactivate the motor(s). In one embodiment, the computer controllers for the conveyor segments 104 can be networked using a bus system to provide power and communications between the individual conveyor segments. Communications to the conveyer 102 can be performed using a network 114 that allows a computer 118 to monitor and control individual conveyor segments 104.

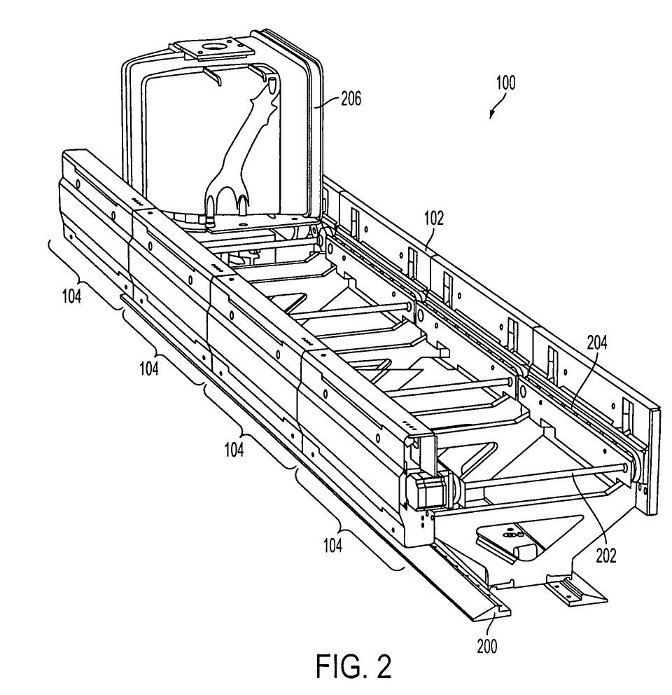

FIG. 2 is an exemplary view of the processing area 100 in accordance with one embodiment of the present invention. In this exemplary embodiment, four conveyor segments 104 make up the conveyor 102. To extend the length of the conveyor 102, more conveyor segments 104 can be added. Director sections (not shown), which allow turning of conveyor segments can be used to turn direction of a conveyor or move a container from one conveyor 102 to another. In the illustrated example, a FOUP 206 is shown on the conveyor 102, which is capable of moving along belts of cartridge modules 204 within the conveyor 102. In one embodiment, a drive motor provides movement to a belt one side of the conveyor segment 104, and a drive shaft 202 is used to transmit movement to the belt to the other side of the conveyor segment 104.

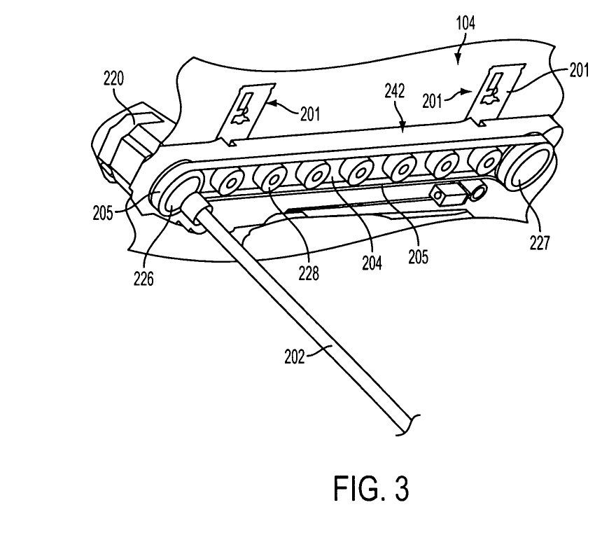

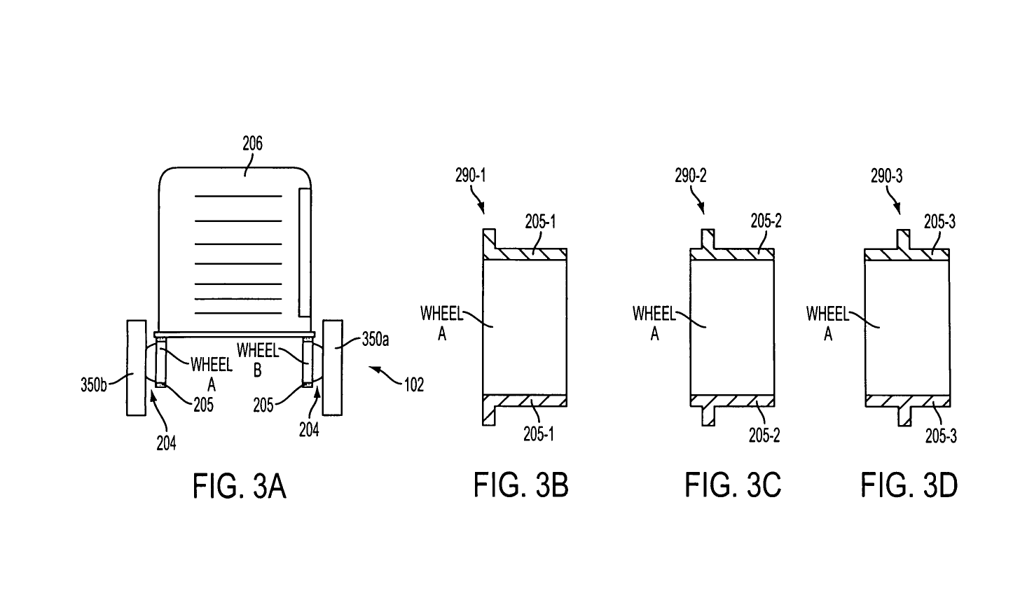

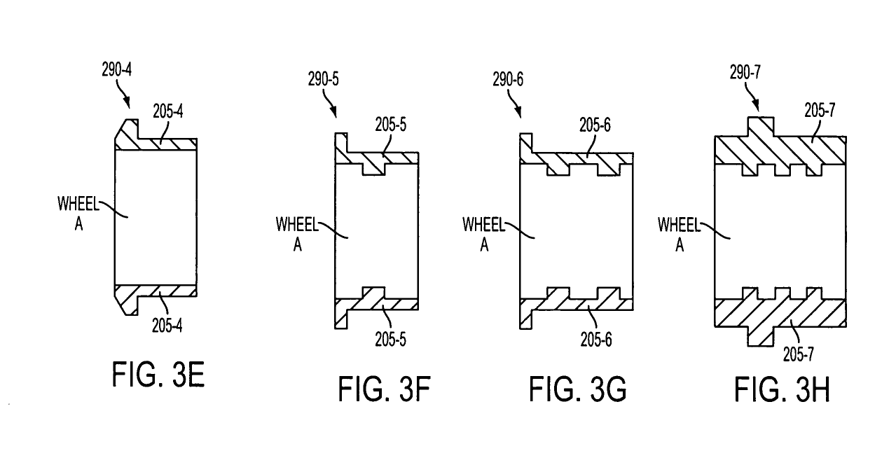

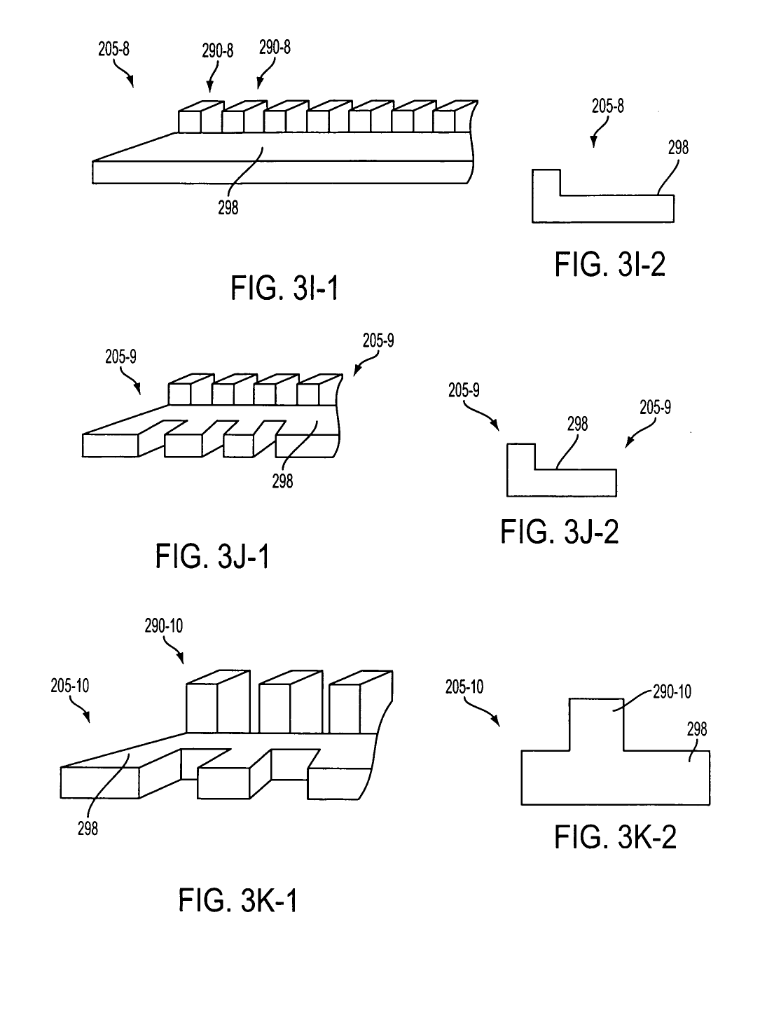

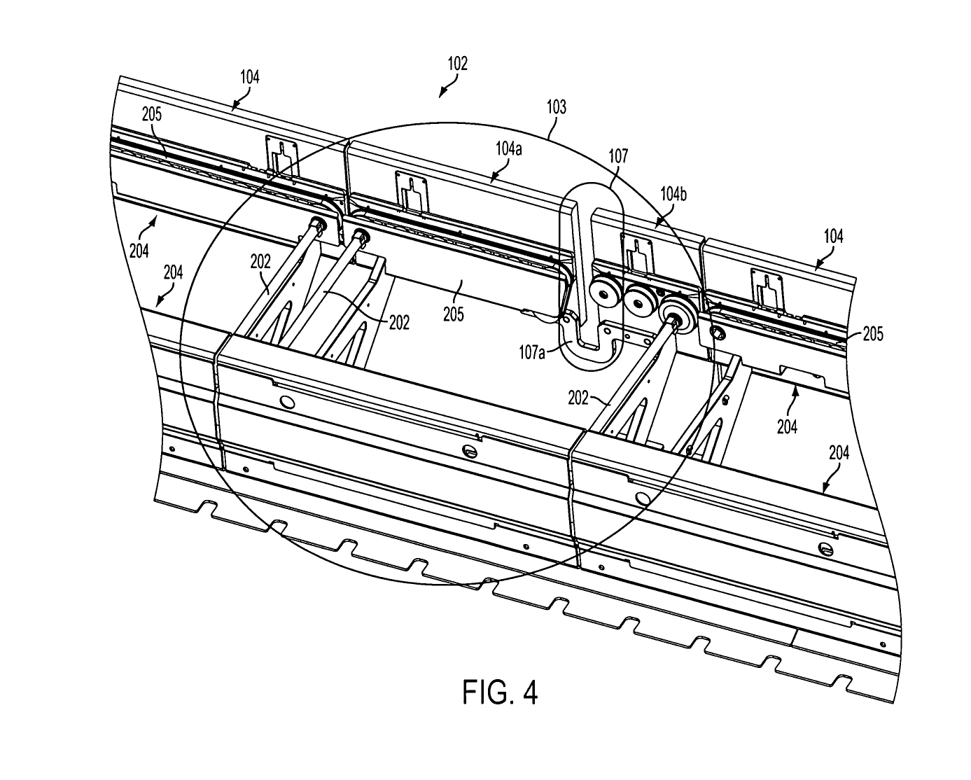

FIG. 3 illustrates a detailed view of a conveyor segment 104, illustrating aspects of a cartridge module 204, in accordance with one embodiment of the present invention. The cartridge module 204 is shown attached to a section of a rail that forms a conveyor segment 104. The conveyor segment 104 also includes position sensors 201, which are placed throughout the conveyor 102 to determine when the FOUP 206 is traveling in a region of the position sensors 201. The position sensors 201 will therefore inform the different conveyor segments 104 that FOUP 206 is traveling in a direction, and the conveyor segments 104 downstream from a current position of the FOUP 204 can activate, so as to transition the FOUP 206 substantially at a current speed down the conveyor 102. In other embodiments, the speed of the different conveyor segments 104 may be adjusted, depending on whether the FOUP 206 is about to make a stop at a local load port area, or if the FOUP 206 is destined for a more distant location down the conveyor 102.

The illustrated detail of the cartridge module 204 includes a plurality of idler wheels 228, which are disposed between a drive pulley wheel 226 and a pulley wheel 227. The idler wheels 228 provide support for belt 205 for when a FOUP travels over the belt 205. The drive pulley wheel 226 is shown being a driven wheel that is connected to a direct drive motor 220. Direct drive motor 220 will therefore turn the drive pulley wheel 226 and cause belt 205 to rotate around pulley wheel 227, and also cause movement of the idler wheels 228. In other embodiments, idler wheels 228 may not move, and can be passive wheels, but may be caused to turn when weight or contact of an object being transported on the belt 205 delivers weight or contact upon belt 205.

The drive pulley wheel 226 is also shown connected to a drive shaft 202. Cartridge 204 is also positioned opposite the drive shaft 202 so as to provide a belt 205 substantially parallel to belt 205 of the shown cartridge module 204. The two parallel belts will therefore allow an object to be transported down the conveyor 202, as it passes the various conveyor segments 104. In one embodiment, the cartridge module 204 (not shown) that is opposite the shown cartridge module 204 may not include a direct drive motor 220. In such a case, the direct drive motor 220 will act to drive the opposite cartridge module 204 by way of the drive shaft 202. In yet another embodiment, the drive shaft 202 may be omitted, thus allowing for independent drive motors 220 to drive the belts 205 of each side of the conveyor rails.

The cartridge module 204 can therefore be installed and removed from the conveyor beam section 104a by simply removing the cartridge plate 204 from the wall or beam. When the cartridge module 204 is removed, all parts are connected to the cartridge plate 242. As such, it is possible to remove the cartridge module 204 quickly and rapidly from a section of the conveyor—on one or both sides of a section. As noted, removal of the cartridge module 204 may be necessary for either maintenance, repair, or installation of a new cartridge module 204 with very little downtime. Additionally, if a particular cartridge module 204 is being removed, or replaced, it is possible to continue operational use of the remaining cartridge modules of the conveyor system while the particular section is in service or is quickly replaced.

As illustrated, the cartridge module 204 (and conveyor segments 104) may then be repeated over and over again for different sections of the conveyor system, and each of the cartridge modules are capable of being installed and removed in an efficient manner as a unit when connected or disconnected to the beam of the conveyor system. The cartridge modules 204 can also take on any number of lengths, depending on its operation or configuration. One example length can be about 0.25 meter, about 0.5 meter, about 0.75 meter, about 1.0 meter, about 1.5 meter, about 2 meter, etc., depending on its application.

FIG. 3A illustrates an example where the conveyor beams 350a and 350b are provided so as to receive cartridge modules 204 that support wheels, and in turn support belts 205. Belts 205 can then rotate along the wheels of the cartridge module 204 so as to move a FOUP 206 along conveyor 102. FIGS. 3B through 3H are provided to illustrate examples of the belt 205. Belt 205 is provided with a raised guide 290 so as to maintain the FOUP 206 within the conveyor 102, when two belts 205 at opposing sides turn so as to transport FOUP 206 along conveyor 102. The illustration of FIG. 3B shows a wheel having a belt 205-1, and a raised guide 290-1. Raised guide 290-1 is configured at an outer edge of wheel A. Wheel A is illustrated in FIG. 3A as the left wheel, and wheel B is illustrated as the right wheel.

The individual endless belts 205 wrap around wheel A, and around wheel B, along the left and right side of the conveyor, so as to support FOUP 206. The belts 205 illustrated in FIGS. 3B through 3H are therefore all with respect to wheel A, and the FOUP will be sitting to the right of the left edge illustrated in FIG. 3B. In FIG. 3C, the belt has a raised guide 290-2, such that the raised portion is away from the edge to define belt 205-2. The raised guide 290-3 is illustrated for belt 205-3 of FIG. 3D. The raised guide 290-4 is illustrated for belt 205-4 in FIG. 3E. The raised guide 290-5 is illustrated for belt 205-5 in FIG. 3F. FIG. 3F has another feature where part of belt 205-5 is indented into a slot of wheel A. In FIG. 3G, two slots are defined in wheel A so that belt 205-6 can fit and be guided (with reduced slippage) and supported within wheel A. FIG. 3H illustrates another embodiment where multiple guides are provided in wheel A and belt 205-7 mates with the guides so as to maintain belt 205-7 on wheel A. The guide 290-7 of FIG. 3H is shown located in yet another position over the surface of the belt 205-7.

FIGS. 3I-1 and 3I-2 illustrate an embodiment of belt 205-8, in accordance with one embodiment of the present invention. The belt 205-8 has a support surface 298 for supporting a FOUP 206, for example. The belt 205-8 also includes raised guides 290-8. A cross-sectional view of this embodiment is shown in FIG. 3I-2. FIGS. 3J-1 and 3J-2 illustrate another embodiment of belt 205-9. Belt 205-9 includes support surface 298, as well as the raised guides 205-9. In this embodiment, the support surface 298 is also provided with slots to segment belt 205-9. The raised guides 205-9 are also segmented, as are raised guides 290-8 of FIG. 3I. By providing segmented raised guides, it is possible to introduce additional flexibility to belts 205, which can extend the longevity of the belt during operation. In one embodiment, the discontinuous belt also reduces the bending forces on the belt, and thus improves the drive and efficiency.

FIGS. 3K-1 and 3K-2 illustrate yet another embodiment of belt 205-10. Belt 205-10 illustrates larger raised guides 290-10 and larger segmentation of the support surface 298. Additionally, FIG. 3K-2 illustrates a belt 205-10, having the raised guide 290-10 spaced apart from the edge of the belt surface 298. By spacing apart the raised guides 290-10 by some degree, it is possible to introduce additional stability to the raised guides 290-10 and additional longevity during its use along a conveyor system.

FIG. 4 illustrates a more detailed view of the conveyor 102 and the conveyor segments 104. In this example, a load port interface segment 103 is provided, which is designed to interface with a load port module. The load port (not shown), is designed to be placed substantially adjacent to the conveyor 102. As will be shown, the slot 107 in the conveyor beam defines sub-segment 104a and sub-segment 104b, and provides a path for an arm of a direct load system to pass there-between. When the arm of the load port system traverses through slot 107 of the conveyor segment 104a/104b, the arm of the load port system allows a support plate to sit and nest between the beams of the conveyor 102. The support of the load port system is therefore lowered into the space between the beams that define the conveyor segments 104.

The support beam plates between the beams of the conveyor 102 allows for FOUPs to travel on belts 205, along the conveyor 102 unobstructed. Specifically, when the arm that is lowered through slot 107 to allow the support into a space between the beams of the conveyor segments, FOUPs traveling and/or sitting on top of the belts 205 will not be impeded from traversing the location of the support, thus being allowed to travel down the conveyor 102. More detail will be provided below regarding the functionality of slot 107.

However, it is an aspect of the present invention that the conveyor segments 104 be modular and each include their own cartridge modules 204, attached to the frames of the beams that define the conveyor segments 104. Although not shown for ease of three-dimensional illustration, the cartridge modules 204 are located on both sides of the conveyor segments 104, as illustrated by the pointing indicators. The belt 205 will therefore be positioned on both sides of the conveyor segments 104 to provide a surface on which a FOUP 206 can travel down the conveyor 102.

Also illustrated are the drive shafts 202 which connect the wheels of the opposing cartridge modules 204 to allow driving of the belt 205 at substantially the same speed. By providing a driveshaft 202, it is also possible to provide a single drive motor for each conveyor segment 104. A single motor can be provided because the drive motor can drive the drive shaft 202, which transfers the same rotation to the opposing cartridge module 204, thus moving the belts 205 in a substantially synchronous speed. As noted above, in alternative embodiments, it is possible to include a motor on each side of the conveyor segments 104, thus eliminating the need for a drive shaft 202.

Further illustrated in the load port interface segment 103 is a connector 107a. Connector 107a is configured in this embodiment to connect sub-segment 104a to sub-segment 104b. Connector 107a also provides a U-shaped configuration to allow the arm of the load port to drop below the level of the beam that defines sub-section 104a of sub-section 104b. In other embodiments, it may be sufficient to provide a straight connector 107a, without a U-bend at the bottom. In still another embodiment, connector 107a may be eliminated altogether, and replaced by an integral connecting piece of sub-segment 104a and sub-segment 104b. If connector 107a is an integral piece of sub-segment 104a and sub-segment 104b, the slot 107 may be less deep than is provided when a U-connector couples the segments. In still another embodiment, it may be possible to connect the sub-segments 104a and 104b by implementing a deeper sub-segment wall, thus providing a lower drop in the slot 107 without the need for a U-shaped connector. Accordingly, it should be understood that connector 107a is only one example of a way to connect a section that has been provided with a slot 107, that is built into a sidewall of the conveyor 102.

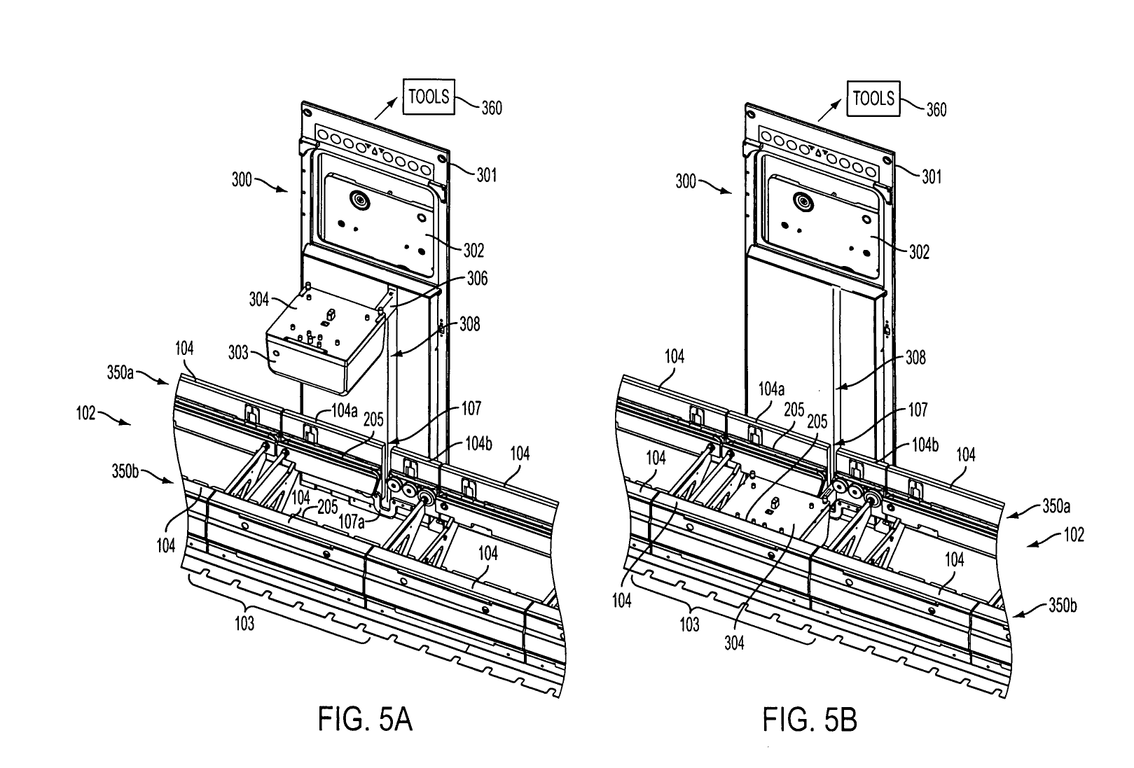

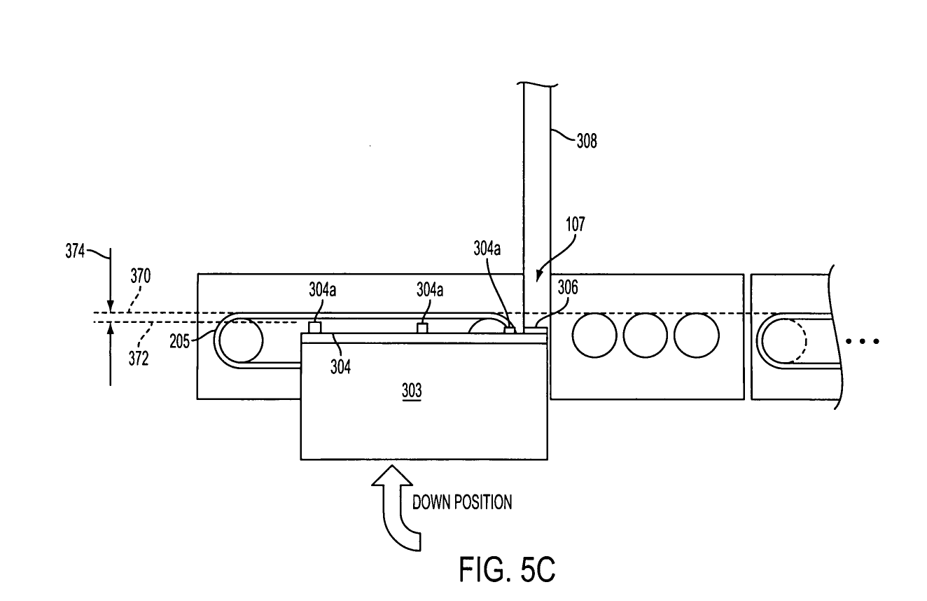

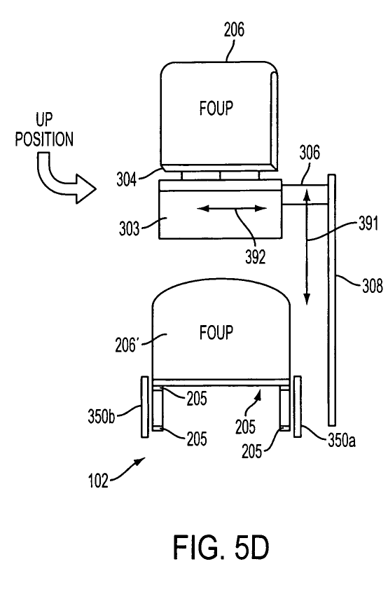

As shown in FIG. 5A, the conveyor 102 is provided with a plurality of conveyor segments 104. Conveyor segments 104 are aligned along a conveyor path so as to provide a path for FOUP 206 to travel from a first point to a second point. FOUP 206 can also be made to travel along conveyor 102 and stop at a load port 300. As shown, load port 300 is a system that allows for the loading of FOUPs 206 that may be traveling on conveyor 102 directly to tools 360.

A FOUP 206 is configured to sit upon of a kinematic plate 304, which is held by an arm 306. Arm 306 is configured to travel along a track 308 in a vertical direction from a point located below a conveyor path and up toward a load port door 302. Load port door 302 is configured to mate with a door of FOUP 206, when FOUP 206 is supported on kinematic plate 304. Kinematic plate 304 is coupled to or is integrated to a support 303, that is also connected to and supported by arm 306. Arm 306 can be coupled directly to the support 303, or parts that integrate the support to the kinematic plate 304.

Arm 306 will travel along track 308 to place support 303 between beam segments 350a and 350b. A slot 107 is also provided in beam segment 350a. The conveyor segment having the slot 107 is defined to be the load port interface segment 103, as described with reference to FIG. 4. The various conveyor segments 104 will also include the cartridge modules 204 that hold and move the belt 205 to allow the transport and movement of FOUPs along conveyor 102.

The arm 306, which is shown connected to a box opener/loader-to-tool standard (BOLTS) interface 301 of the load port 300 is provided with simple up-down movement and the vertical direction from a near floor location up to a location of the load port door 302. By providing the simple up-down movement along track 308, arm 306 can lower support 303 and the kinematic plate 304 into a region between beam segments 350a and 350b of the conveyor 102. The support 303 is configured to drop in between the beam segments 350 so as to lower the kinematic plate 304 to a position that is at least below a level of the belt 205. By lowering the kinematic plate 304 below a level of the belt 205, it is possible to use conveyor 102 to transport FOUPs 206 that are not destined to load port 300.

As such, FOUPs traveling along conveyor 102 will not be impeded from transporting along a system that is adjacent to load port 300 simply because load port 300 has the support 303 in a lowered position. When the support 303 and associated kinematic plate 304 are in the raised position (which is currently shown), FOUPs traveling along the conveyor 102 can continue to travel without being obstructed by support 303. Accordingly, it is possible to transport FOUPs along conveyor 102 either when the support 303 is in a lowered position that is between beam segments 350a and 350b or when the support 303 is in a raised position such that arm 306 places support 303 and kinematic plate 304 at the raised position (proximate to or at the load port door 302).

FIG. 5B illustrates the arm 306 being placed in a lowered position where the kinematic plate 304 lies below a level of the belt 205 within the conveyor 102. FIG. 5C illustrates a more detailed diagram of an example kinematic plate 304 and kinematic pins 304a being placed in a lowered position by support 303 and arm 306. As shown, the kinematic pins 304a are placed at a position that is just below the level of the belt. The belt position 370 is therefore shown being separated from a kinematic pin position 372 by a minimum separation distance 374. The minimum separation distance 374 is such that any possible movement of belt 205 or material on belt 205 does not impede a FOUP traveling over the belt. In one embodiment, is desired that contact with the kinematic pins 304a, that are placed at the kinematic pin position 372, do not obstruct the traveling FOUP. Also shown in FIG. 5C, is the position of the arm 306, when placed through slot 107. More examples of the kinematic pins are shown in U.S. Pat. No. 6,435,330, which is incorporated by reference.

In one alternative embodiment, the belts can be eliminated, and in place, rollers can be used. Examples of the rollers are shown in FIG. 1A. Thus, although FIG. 1A shows a prior art configuration that does not allow nesting of the support by a single arm 306, the rollers (e.g., conveying wheels) of FIG. 1A can be used in place of the belt configuration. If the rollers are used, the transport level provided by the rollers should be above the level of the Kinematic plate 304. Consequently, all of the embodiments defined herein work well if the belt is replaced to define a second embodiment. Additional roller conveyor examples (e.g., having conveying wheels) are provided in U.S. Pat. No. 6,435,330, which are incorporated by reference. Additionally, the rollers shown and used in U.S. application Ser. No. 11/484,218 (ASTGP135) are also incorporated herein by reference as alternatives to belt embodiments.

Accordingly, the kinematic plate 304 is lowered by a single arm 306 traveling on a single track 308 that is part of a load port 300, in accordance with one embodiment of the present invention. As further illustrated, the single arm 306 connects to support 303 at one point of the support 303. The connection of arm 306 to the support 303 is such that sufficient weight can be lowered and raised in a steady and accurate motion when the kinematic plate 304 receives a FOUP 206 and lowers it or raises it between the load port door 302 and the down position illustrated in FIG. 5C.

In one embodiment, the track 308 can implement a single slide mechanism. For instance, the single slide mechanism can include a single linear bearing, to provide smooth support for the arm 306 as it slides up and down. In one embodiment, the single linear bearing uses a linear motion mechanism utilizing the rotational motion of ball elements.

In some embodiments, a bearing can be a ball bearing. The purpose of a ball bearing is to reduce rotational friction and support radial and axial loads. It achieves this by using at least two races to contain the balls and transmit the loads through the balls. Usually one of the races is held fixed. As one of the bearing races rotates it causes the balls to rotate as well. Because the balls are rolling they have a much lower coefficient of friction than if two flat surfaces were rotating on each other.

Providing a single arm is, in one embodiment, very beneficial for a number of reasons, and overcomes many problems. For examples, by only providing one slot and arm in the load port, it is possible to reduce the number of moving parts. It is also possible to reduce the potential for particle generation in a clean environment. Further, it is possible to reduce the number of slots 107 in the conveyor segments 107. By only providing one slot 107, a more simple design is possible, thus allowing for more simple lowering of the support 303 in the nested orientation. Accordingly, the simplicity in design, the ease of integration and clean room compatibility overcome may of the issues facing more complex load port deigns.

In the up position illustrated in 5D, the FOUP 206 that is raised and in the position adjacent to load port door 302 does not impact a FOUP 206′ that is traveling on the belt 205 down the conveyor 102. As illustrated, the beam segment 350b and beam segment 350a are configured to receive the cartridge modules 204 such that belts 205 can move FOUP 206′ down the conveyor 102 when one FOUP 206 is in the up position.

FIG. 5D also illustrates that the arm 306 and support 303 can be provided with horizontal movement 392, as well as vertical movement 391 that moves arm 306 through track 308. The horizontal movement 392 can be used to place a FOUP closer to the load port door to allow interfacing. In other embodiments, it may be possible to only provide vertical movement 391.

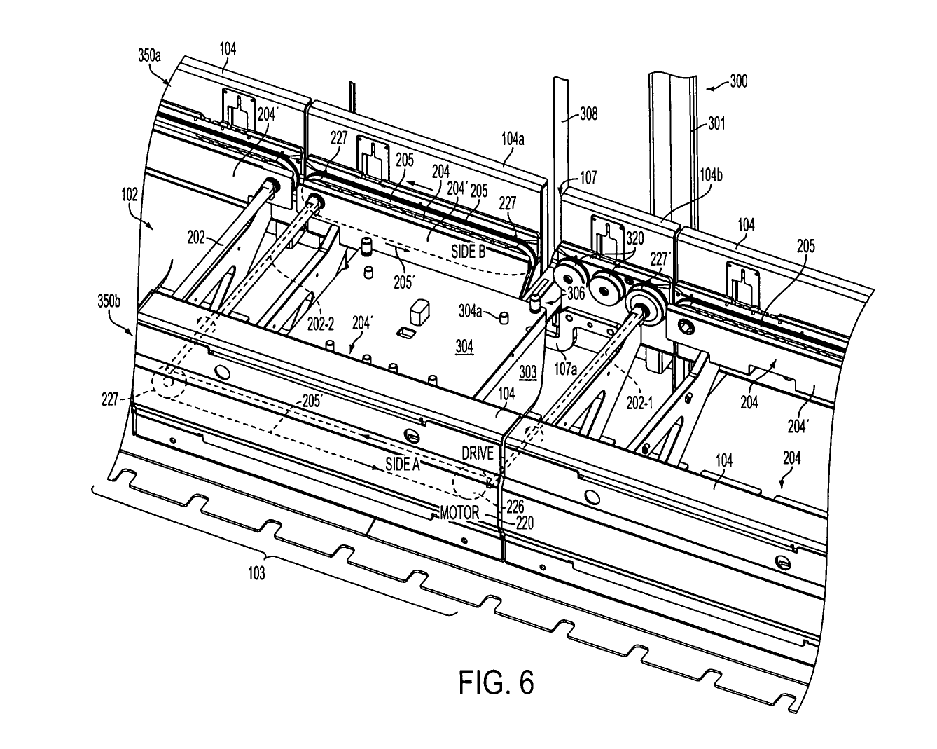

FIG. 6 illustrates in more detail, the load port interface segment 103, in accordance with one embodiment of the present invention. As shown, slot 107 is defined within the conveyor segment 104a and 104b. Within the load port interface segment 103, a first drive shaft 202-1 and a second drive shaft 202-2 are provided so as to allow rotation of belts 205 on both the side where beam segment 350a and beam segment 350b reside. Thus, a belt 205 is provided on each beam segment in an orientation that is substantially parallel to each other, so as to allow the belts 205 to transport a FOUP 206 between different locations of a fabrication facility. In one embodiment, a motor 220 is configured to drive the load port interface segment 103. Motor 220 is configured on the beam segment 350b side of the conveyor 102. The motor 220 will therefore turn the belt along belt path 205′ so as to move wheel 227. The rotation of wheel 227 will then turn drive shaft 202-2 along the same direction as the belt path 205′ on side A. The drive shaft 202-2 will in turn, turn wheel 227 on side B. Turning wheel 227 will therefore cause the belt 205 to turn on belt path 205′ of side B. Additionally, motor 220 of side A will also cause drive shaft 202-1 to turn so as to move wheel 227′ on the side of beam segment 350a.

In still another embodiment, with reference to FIG. 6, it is possible to connect the motor 220 to the end that has the drive shaft 202-2. If this is done, it is possible to eliminate the drive shaft 202-1. By doing this, wheel 227′ will not be driven, but driving the wheel 227′ and wheels 230 is optional.

Also shown on sub-segment 104b are passive wheels 320 that are aligned with wheel 227′. In one embodiment, wheels 320 are passive wheels (e.g., not driven). In other embodiments, the wheels 320 can be driven or connected to a belt if desired. For example, a belt may be provided around just the two wheels 320, or around two wheels 320 and 327, to provide a belt path that is defined by three wheels. In other embodiments, no belt is provided on each of the wheels 320 and 327′, and instead, the wheels are provided with a simple surface that allows FOUPs to travel thereupon. The surface of the wheels, when no belt is provided in sub-segment 104b, may be a rubberized surface similar to the surface provided by belt 205.

In this embodiment, the track 308 is shown adjacent and substantially aligned to slot 107, to allow arm 306 to slide between slot 107 and lower kinematic plate 304 and support 303 between the beam segments 350a and 350b. As noted above with reference to FIGS. 5A through 5D, the lowered position allows FOUPs traveling along conveyor 102 to travel unobstructed by the kinematic plate 304 or the kinematic pin 304a.

Still referring to FIG. 6, it is noted that load port interface segment 103 is, in this embodiment, different than conveyor segments 104 in which no load port interface is provided. When no load port interface is provided in a particular conveyor segment 104, the slot 107 is not defined within the conveyor segment. If the conveyor segment is not a load port interface segment 103, the conveyor is provided with a cartridge module on each side of the conveyor segment 104, and a single drive shaft 202. The single drive shaft 202 would be configured to drive the opposing side that does not include a motor. However, as noted above, it is possible to provide a system where no drive shaft 202 is integrated with the conveyor segment 104, and individual motors are provided for each cartridge module 204 to drive the respective belts 205. If separate motors are used and no drive shafts 202 are used, then the motors can be synchronized by a suitable program that connects electronics of the conveyor belt to monitor speed, activation, and associated movement.

In this more detailed illustration, each of the cartridge modules 204 are also provided with a cover 204′. The cover 204′ serves to encase the various wheels that support the belt 205 in each cartridge module 204. Also, it is noted that the cartridge module 204 (as shown in more detail in FIG. 3), can include more or fewer idler wheels 228 along the path that supports the belt 205. The number of idler wheels will depend on the particular configuration, the anticipated wait of FOUPs (loaded and unloaded with wafers), or the type of material being transported.

Although specific examples were described with reference to semiconductor wafer, it should be understood that the type of material can vary and materials other than semiconductor wafers can be transported along the conveyor 102. The conveyor 102 will therefore provide a conveyor system to move material which can be positioned over belts 205 in such a manner to move them from location to location within a fabrication facility. As noted above, in some embodiments, belt 205 can include a raised guide that will ensure that materials placed on top of belts 205 will be supported as well as maintained between the raised guides of each of the belts. In still other embodiments, it is envisioned that the belts 205 surface can take on various configurations, and can have either continuous surfaces, ribbed surfaces, discontinuous surfaces, and the like. Additionally, the raised guide of the belt 205 can also be either continuous, discontinuous, slotted, intermittently slot gaps, posts, walls (continuous or spaced apart), treads, or any other configuration, so long as the raised guide serves to maintain an object (e.g., container) aligned between the belts 205.

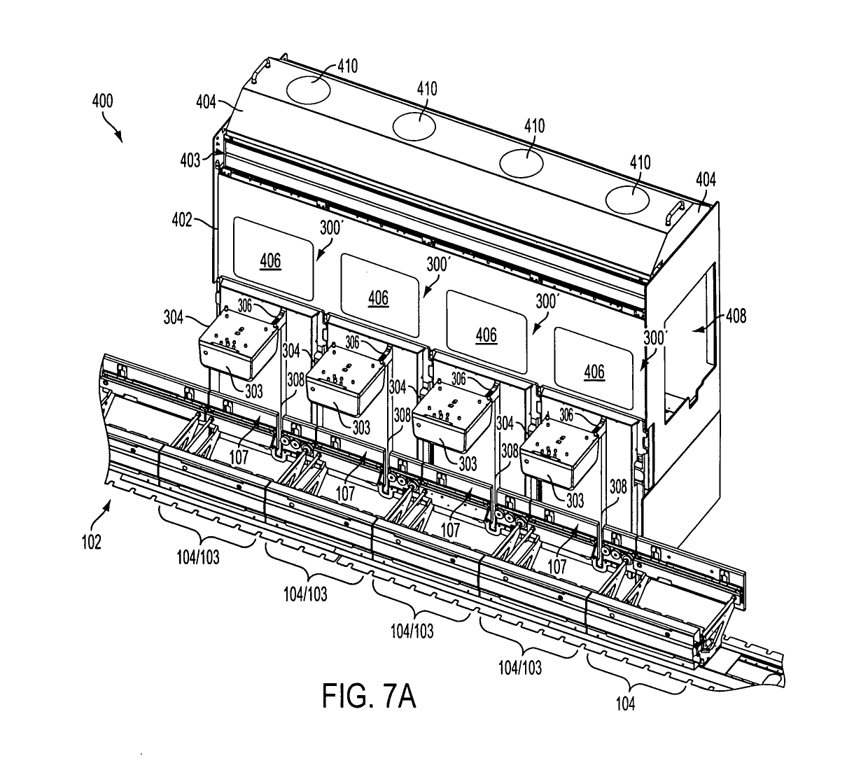

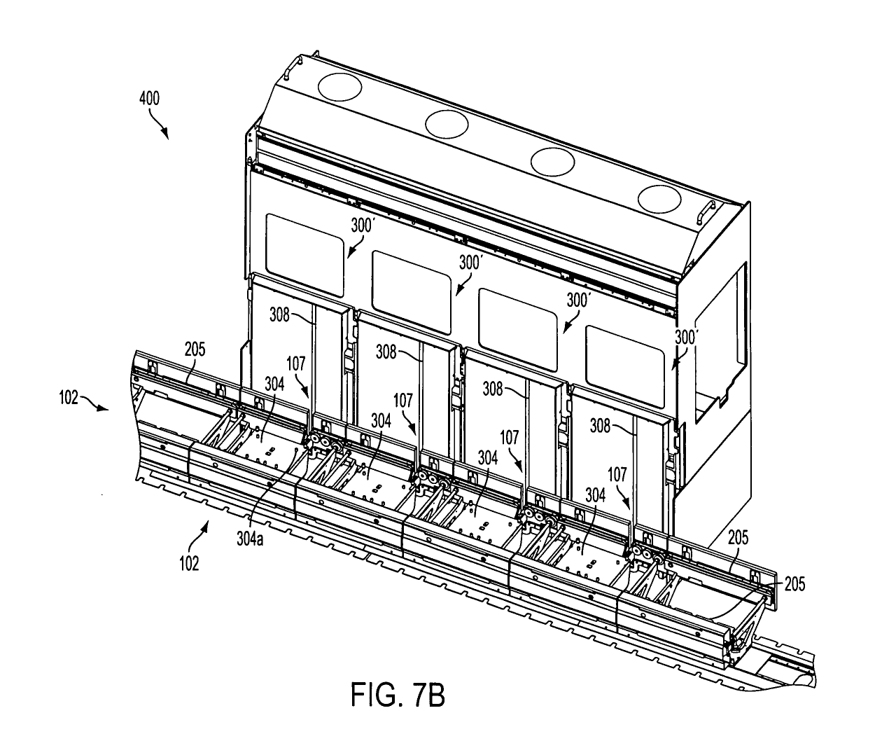

FIG. 7A illustrates a multi-load port system 400, having four load port units 300′, in accordance with one embodiment of the present invention. The load port units 300′ resemble a single load port 300, as illustrated in FIG. 5A, except that the upper portion of the load port unit 300′ is integrated with a housing 402. Housing 402 allows for more integrated control of the load port units 300′, so as to process more material at a certain location where high throughput tools are placed. The housing 402 is shown having a plurality of load port openings 406. Although not shown, the load port openings 406 will include a load port door that is presently in a down position within the housing 402.

The housing 402 will also include end effectors for communicating material (e.g., semiconductor wafers to and from containers that are loaded to each of the load port units 300′.) In this example, the housing 402 will also include a filter 403 that resides on the upper portion of the housing 402. In one embodiment, the filter 403 may be a HEPA filter that ensures that air flow injected into housing 402 is clean, and particles are removed. Above filter 403 is a shell 404 that houses a plurality of fan blowers 410. The fan blowers 410 are shown by a simplified circle on shell 404, representing the path of air flow into the shell 404, through the filter 403, and into housing 402.

Housing 402 also includes an access panel opening 408, which is shown without a door. The door is commonly attached to the access panel opening 408 during operation, but provides a way for providing maintenance to the multi-load port system 400. In this implementation, the conveyor 102 includes a plurality of conveyor segments 104. The conveyor segments 104 that lie in front of each of the load port units 300′ are also load port interface segments 103. By being configured as load port segments 103, each of the load port segments will also include a slot 107 proximate to each of the load port units 300′. The slot 107, as mentioned above, provides access for arm 306 as it slides downward through track 308 and into slot 107.

FIG. 7B illustrates the load port units 308 in a down position, having the support 303 and kinematic plate 304 in a nested position between the beams of the conveyor segments 104. When the load port units 300′ have the support and kinematic plates 304 in the down position, the kinematic plates 304 do not interfere with a path provided by the belts 205 of the conveyor 102. In one embodiment, it is desired that the kinematic plate 304 and kinematic pins 304a do not obstruct the container rolling over the belts 205.

In this example, the multi-load port system 400 includes four load port units 300′, however, more load port units may be clustered as part of the multi-load port system 400 or fewer, depending on the need for loading and unloading containers (e.g., semiconductor wafers) to and from tools serviced by the multi-load port system 400. Additionally, it should be understood that each of the load port units 300′ are capable of operating independently, and are not required to all move up or all move down together. In another embodiment, they are capable of moving up and down together. In general, each of the load port units 300′ are capable of independent operation to allow moving of the support 303 and kinematic plates 304 independently of one another in the up-down position for placing containers in an up position so as to feed semiconductor wafers into and out of containers through the load port opening 406 of housing 402. Still further, it should be understood that the load port units 300′ can also be used to directly load containers from conveyor 102 into stocking facilities. The stocking facilities can include specialized housings that stock containers at different locations along the fabrication facility to allow temporary queuing of material while other fabrication equipment is busy. As such, the load port units 300′ having the direct load capability from conveyor 102 can be flexibly integrated with different types of housings that either provide load port capabilities, or complete transfer of the container into a stocker system.

FIG. 8A illustrates a cross-sectional view of load port 300, in accordance with one embodiment of the present invention. Load port 300 is integrated alongside conveyor 102. In this example, the conveyor 102 includes beam segments 350a and 350b which hold cartridge modules 204. Cartridge modules 204 in turn hold the belt 205 that allows transport of FOUP 206 along conveyor 102. When arm 306 is in a down position, the support 303 and the kinematic plate 304 is placed below the plane that transports the FOUP 206. Arm 306 is shown in a dashed line illustrating that support 303 has dropped below the level of the belt 205. FIG. 5C, as shown above, shows a slot 107 through which arm 306 drops when passing through track 308. Once the correct FOUP 206 arrives at load port 300, the computer system and program running the particular fabrication facility will dictate to load port 300 to raise arm 306. By raising arm 306, FOUP 206 is allowed to be raised off of the belt 205 to a location adjacent to load port door 302.

FIG. 8B illustrates the support 303 raising FOUP 206 to the upper position adjacent to the load port door 302. Load port door 302 also includes latch keys 506 which are configured to mate with keyholes on container door 510. Once in the upper position, arm 306 is configured to move horizontally toward the latch keys 506 as illustrated in FIG. 8C. At this point, gears or other mechanisms within port door 502 turn the latch keys 506, and then pull the container door 510 toward the load port door 302. Once the container door 510 is connected to load port door 302, by way of extension 504 and other mechanisms, the load port door 302 moves horizontally away from FOUP 206 and then down to clear an opening into FOUP 206.

FIG. 8D illustrates a robot 520 capable of moving into and out of the FOUP 206 to either deliver or remove wafers between FOUP 206 and processing tools 530. As illustrated in FIGS. 8B through 8D, another FOUP 206 may be traveling along conveyor 102 while FOUP 206 is interfaced/connected with the load port. Accordingly, it is noted that arm 306 provides vertical movement up and down from the conveyor 102 to a position near an opening of the load port. When in the up position, FOUPs 206 can continue to travel unobstructed on conveyor 102. When in the down position, the support and kinematic plate 304 can rest in a nested position under the plane of the conveyor belt to allow FOUPs 206 to travel if those particular FOUPs 206 are not destined for the particular load port 300.

As previously discussed, the conveyors can include integrated networked communications. These communications allow individual conveyor segments to be controlled by a computer system via a network. The computer system can also execute software that allows individual FOUPs to be transported and stopped at load ports, stockers, or while on the conveyors.

It is also envisioned that it is possible to have an OHT with a kinematic plate, lower the kinematic plate (with an extension) down to a conveyor segment 103. In this embodiment, it is possible for the OHT to pick up a container from the conveyor at locations along a conveyor path. The OHT can then drop the container onto another location of the conveyor 102 or at another bay in a fabrication facility. The OHT can also lift the container onto an OHT track, buffer or stock the container, and then deliver the container to another location on the OHT track or another location on the conveyor 102. The container can then be moved to the desired location for transfer by a load port or a socking device. Although containers can refer to FOUPs, which carry semiconductor wafers, other substrates can also be transported on the conveyor and lifted by a load port. Thus, instead of containers, it is envisioned that other material that is flat enough to travel on belts, rollers, or sliders, can also be transported. Additionally, although specific embodiments define “load ports”, it should be understood that other systems that load directly from a conveyor may also be used. Other systems that can load from a conveyor, using a single arm can include, by way of example and without limitation, a stocker, a loader, a process tool, a storage, an overhead transport vehicle, etc.

Many advantages are presented by implementing a single arm 306. These advantages also overcome many problems. The single arm 306, for example, allows the system to provide only one track in the front of the load port. This cuts down in the number of moving parts, in locations that require very clean environment qualifications. Thus, particle generation is reduced. Further, it is possible to reduce the number of slots 107 in the conveyor segments 107. By only providing one slot 107, a more simple design is possible, thus allowing for more simple lowering of the support 303 in the nested orientation. Accordingly, the simplicity in design, the ease of integration and clean room compatibility overcome may of the issues facing more complex load port and conveyor deigns.

The invention may be practiced with other computer system configurations including computing devices, hand-held devices, microprocessor systems, microprocessor-based or programmable consumer electronics, minicomputers, mainframe computers and the like. The invention may also be practiced in distributing computing environments where tasks are performed by remote processing devices that are linked through a network. For instance, on-line gaming systems and software may also be used.

With the above embodiments in mind, it should be understood that the invention may employ various computer-implemented operations involving data stored in computer systems. These operations are those requiring physical manipulation of physical quantities. Usually, though not necessarily, these quantities take the form of electrical or magnetic signals capable of being stored, transferred, combined, compared, and otherwise manipulated. Further, the manipulations performed are often referred to in terms, such as producing, identifying, determining, or comparing.

Any of the operations described herein that form part of the invention are useful machine operations. The invention also relates to a device or an apparatus for performing these operations. The apparatus may be specially constructed for the required purposes, such as the carrier network discussed above, or it may be a general purpose computer selectively activated or configured by a computer program stored in the computer. In particular, various general purpose machines may be used with computer programs written in accordance with the teachings herein, or it may be more convenient to construct a more specialized apparatus to perform the required operations.

The invention can also be embodied as computer readable code on a computer readable medium. The computer readable medium may be any data storage device that can store data, which can thereafter be read by a computer system. Examples of the computer readable medium include hard drives, network attached storage (NAS), read-only memory, random-access memory, FLASH based memory, CD-ROMs, CD-Rs, CD-RWs, DVDs, magnetic tapes, and other optical and non-optical data storage devices. The computer readable medium can also be distributed over a network coupled computer systems so that the computer readable code may be stored and executed in a distributed fashion.

While this invention has been described in terms of several preferred embodiments, it will be appreciated that those skilled in the art upon reading the preceding specifications and studying the drawings will realize various alterations, additions, permutations and equivalents thereof. It is therefore intended that the present invention includes all such alterations, additions, permutations, and equivalents as fall within the true spirit and scope of the invention.

What is claimed is:

1. A direct loading tool, comprising:
(a) a conveyor oriented along a direction, the conveyor being integrated proximate to first position, the conveyor including,
(i) a first beam and a second beam, each of the first and second beams support wheels that respectively move a first belt and second belt, wherein the first beam and the second beam are spaced apart in a parallel orientation, the first beam including a single slot;
(b) a load port oriented adjacent to the first beam of the conveyor, the load port including,
(i) a load port opening defined proximate to a second position;
(ii) a track defined along a vertical direction between the first position of the conveyor and the second position;
(iii) a single arm configured to move along the track between the first position and the second position, such that the single arm is configured to move through the single slot when positioned at the first position; and
(iv) a support connected to the single arm, the support being moved in the vertical direction so as to place the support between the first and second beams when the single arm is in the single slot at the first position.

2. The direct loading tool of claim 1, wherein the first position in adjacent to a floor and the second position away from the floor.

3. The direct loading tool of claim 1, wherein the first and second belts are at a belt path height and the support, when placed between the first and second beams is below the path height.

4. The direct loading tool of claim 1, wherein a container is supported by the first and second belt of the conveyor.

5. The direct loading tool of claim 1, wherein the support includes a kinematic plate, and the kinematic plate is placed below a level of the first and second belts when in the first position.

6. The direct loading tool of claim 4, wherein the kinematic plate of the support couples to a base of the container, the single arm configured to lift the container off of the first and second belts and position the container proximate to the second position.

7. The direct loading tool of claim 6, wherein the single arm has a horizontal link, for moving the single arm horizontally when in the second position.

8. The direct loading tool of claim 1, wherein the first beam and the second beam define a conveyor segment, and a plurality of conveyor segments are coupled to define the conveyor.

9. The direct loading tool of claim 8, wherein certain ones of the conveyor segments include the single slot.

10. The direct loading tool of claim 1, wherein the first and second belt is an endless belt.

11. The direct loading tool of claim 10, wherein each of the first and second belts includes a support surface and raised guides.

12. The direct loading tool of claim 11, wherein the support surface is one of continuous, planar, ribbed, pebbled, or discontinuous.

13. The direct loading tool of claim 11, wherein the raised guide is one of continuous, planar, ribbed, pebbled, or discontinuous.

14. The direct loading tool of claim 8, wherein the wheels that move each of the first and second belts are integrated on a cartridge module.

15. The direct loading tool of claim 14, wherein each conveyor segment includes at least two of the cartridge modules.

16. The direct loading tool of claim 15, wherein at least one cartridge module on each conveyor segment includes a motor.

18. The direct loading tool of claim 16, further including at least one drive shaft in each conveyor segment.

19. The direct loading tool of claim 1, wherein the load port is interfaced with semiconductor processing tools.

20. The direct loading tool of claim 1, wherein the support being between the first and second beams places the support in a nested orientation between the belts of the conveyor, the nested orientation providing clearance for containers to travel on the belts without obstruction.

21. The direct loading tool of claim 1, wherein the track implements a single linear bearing.

22. A direct loading tool, comprising:
(a) a conveyor oriented along a direction, the conveyor being integrated proximate to first position, the conveyor including,
(i) a first beam and a second beam, each of the first and second beams support wheels that respectively move a conveying wheels, wherein the first beam and the second beam are spaced apart in a parallel orientation, the first beam including a single slot;
(b) a load port oriented adjacent to the first beam of the conveyor, the load port including,
(i) a load port opening defined proximate to a second position;
(ii) a track defined along a vertical direction between the first position of the conveyor and the second position;
(iii) a single arm configured to move along the track between the first position and the second position, such that the single arm is configured to move through the single slot when positioned at the first position; and
(iv) a support connected to the single arm, the support being moved in the vertical direction so as to place the support between the first and second beams when the single arm is in the single slot at the first position.

23. The direct loading tool of claim 22, wherein the support being between the first and second beams places the support in a nested orientation between the conveying wheels of the conveyor, the nested orientation providing clearance for containers to travel on the conveying wheels without obstruction.

24. The direct loading tool of claim 22, wherein the track implements a single linear bearing.
